(19) United States
(12) Patent Application Publication
(10) Pub. No.: US 2024/0178281 A1
(43) Pub. Date: May 30, 2024

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/319,379

(22) Filed: May 17, 2023

(30) Foreign Application Priority Data
Nov. 29, 2022 (CN) 202211513766.0

(51) Int. Cl. H01L 29/20; H01L 29/66; H01L 29/778

(52) U.S. Cl. CPC H01L 29/2003; H01L 29/66462; H01L 29/7787

(57) ABSTRACT

Disclosed are a semiconductor structure and a manufacturing method thereof. The semiconductor structure includes: a substrate, a channel layer, a barrier layer and a P-type semiconductor layer stacked sequentially. The barrier layer includes a first region and an oxygen-doped region, an oxygen concentration of the oxygen-doped region is higher than that of the first region, and a projection of the oxygen-doped region on the substrate at least partially overlaps with a projection of the P-type semiconductor layer on the substrate. When the semiconductor device is in an off state, 2DEG may be depleted to obtain an enhancement-mode device, and the oxygen-doped region with a larger unit cell parameter and a wider band gap is obtained by performing an oxygen doping process. Under an electric field, an energy band between the barrier layer and the P-type semiconductor bends more, which increases a barrier height, reduces leakage current, and improves power characteristics.

### CROSS-REFERENCE TO RELATED APPLICATIONS

This disclosure claims priority to Chinese Patent Application No. 202211513766.0, filed on Nov. 29, 2022, which is hereby incorporated by reference in its entirety.

### TECHNICAL FIELD

The present disclosure relates to the field of semiconductor technology, in particular, to a semiconductor structure and a manufacturing method thereof.

### BACKGROUND

Generally, GaN-based high electron mobility transistor (HEMT) devices are depletion-mode field effect transistors. For example, in radio-frequency microwave applications, turn-on voltages need to be negative, which results in that a circuit structure is complicated and a circuit's protection function against false start is also affected, reducing safety of the circuit, therefore it is necessary to carry out research on enhancement-mode GaN-based HEMT devices.

For P-type gate technology, during its manufacturing process of the device, it is necessary to etch off the P-type GaN-based epitaxial layer between the gate electrode and the drain electrode, which makes it difficult to control etching accuracy and introduce etching damage, and eventually leads to a decrease in output current density and device stability and an increase of leakage current of the gate electrode.

### SUMMARY

In view of this, embodiments of the present disclosure provide a semiconductor structure and a manufacturing method thereof to solve a technical problem of gate leakage current of a power device in related technology.

According to an aspect of the present disclosure, a semiconductor structure provided by an embodiment of the present disclosure includes: a substrate, a channel layer, a barrier layer and a P-type semiconductor layer stacked sequentially, where the barrier layer includes an oxygen-doped region and a first region, an oxygen concentration of the oxygen-doped region is higher than an oxygen concentration of the first region, the oxygen-doped region is arranged on a side of the first region away from the substrate, and a projection of the oxygen-doped region on the substrate at least partially overlaps with a projection of the P-type semiconductor layer on the substrate.

In an embodiment, a surface of the oxygen-doped region away from the substrate and a surface of the first region away from the substrate are in the same plane.

In an embodiment, a projection area of the P-type semiconductor layer on the substrate is less than or equal to a projection area of the oxygen-doped region on the substrate.

In an embodiment, a thickness of the oxygen-doped region ranges from 1 nm to 50 nm along a direction perpendicular to a plane where the substrate is located.

In an embodiment, the P-type semiconductor layer includes a passivation layer and a first P-type layer; the passivation layer is arranged on a side of the first P-type layer away from the substrate; and a hydrogen concentration of the passivation layer is higher than a hydrogen concentration of the first P-type layer.

In an embodiment, a thickness of the passivation layer ranges from 1 nm to 60 nm.

In an embodiment, the semiconductor structure further includes: a gate dielectric layer arranged between the barrier layer and the P-type semiconductor layer, where a projection of the gate dielectric layer on the substrate at least partially overlaps with a projection of the oxygen-doped region on the substrate, and the gate dielectric layer includes oxides.

In an embodiment, the semiconductor structure further includes: a gate electrode arranged on a side of the P-type semiconductor layer away from the substrate, a source electrode and a drain electrode arranged on a side of the barrier layer away from the substrate, where the source electrode and the drain electrode are separately arranged on either side of the gate electrode.

In an embodiment, the barrier layer further includes a second region arranged on a side of the oxygen-doped region away from the first region, where the oxygen concentration of the oxygen-doped region is higher than an oxygen concentration of the second region.

In an embodiment, an oxygen concentration of the oxygen-doped region decreases first and then increases in a direction parallel to the substrate.

In an embodiment, a thickness of the oxygen-doped region decreases first and then increases in a direction parallel to the substrate.

According to another aspect of the present disclosure, a manufacturing method of the semiconductor structure provided by an embodiment of the present disclosure includes: epitaxially forming a channel layer, a barrier layer and a P-type semiconductor material layer on a side of the substrate sequentially; and performing an oxygen doping process to the P-type semiconductor material layer and at least part of the barrier layer; where the P-type semiconductor material layer is activated and transformed to a P-type semiconductor layer, and the at least part of the barrier layer processed by oxygen doping forms an oxygen-doped region, and remaining part of the barrier layer is a first region, an oxygen concentration of the oxygen-doped region is higher than an oxygen concentration of the first region, and the oxygen-doped region is arranged on a side of the first region away from the substrate, and a projection of the oxygen-doped region on the substrate at least partially overlaps with a projection of the P-type semiconductor layer on the substrate.

In an embodiment, the oxygen doping process includes any one of oxygen ion implantation, oxygen ion diffusion and ozone process.

In an embodiment, the manufacturing method further includes: performing a passivation process to a side of the P-type semiconductor layer away from the substrate to form a passivation layer, where a remaining part of the P-type semiconductor layer becoming a first P-type layer, the passivation layer is arranged on the side of the first P-type layer away from the substrate, and a hydrogen concentration of the passivation layer is higher than a hydrogen concentration of the first P-type layer.

In an embodiment, the performing a passivation process to a side of the P-type semiconductor layer away from the substrate to form a passivation layer with remaining part of the P-type semiconductor layer becoming a first P-type layer includes: depositing a protective dielectric layer on the side of the P-type semiconductor layer away from the substrate; and performing the passivation process to a side of the protective dielectric layer away from the substrate and the side of the P-type semiconductor layer away from the substrate.

In an embodiment, the manufacturing method further includes: performing a passivation process on a side of the P-type semiconductor layer away from the substrate to form a passivation layer simultaneously with the oxygen doping process, where a remaining part of the P-type semiconductor layer becomes a first P-type layer, the passivation layer is arranged on a side of the first P-type layer away from the substrate, and a hydrogen concentration of the passivation layer is higher than a hydrogen concentration of the first P-type layer.

According to still another aspect of the present disclosure, a manufacturing method of a semiconductor structure provided by an embodiment of the present disclosure includes: epitaxially forming a channel layer and a first region of a barrier layer on a side of a substrate sequentially; epitaxially forming an oxygen-doped region of the barrier layer on a side of the first region away from the substrate by introducing a gas source containing oxygen element, where an oxygen concentration of the oxygen-doped region is higher than an oxygen concentration of the first region and the oxygen-doped region is arranged on a side of the first region away from the substrate; and forming a P-type semiconductor material layer on a side of the oxygen-doped region away from the substrate, where the P-type semiconductor material layer is activated and transformed into a P-type semiconductor layer and a projection of the oxygen-doped region on the substrate at least partially overlaps with a projection of the P-type semiconductor layer on the substrate.

### BRIEF DESCRIPTION OF THE DRAWINGS

FIG. 1 is a schematic diagram of a semiconductor structure provided by an embodiment of the present disclosure.

FIG. 2 is a schematic diagram of a semiconductor structure provided by an embodiment of the present disclosure.

FIG. 3 is a schematic diagram of a semiconductor structure provided by an embodiment of the present disclosure.

FIG. 4 is a schematic diagram of a semiconductor structure provided by an embodiment of the present disclosure.

FIG. 5 is a schematic diagram of a semiconductor structure provided by an embodiment of the present disclosure.

FIG. 6 is a schematic diagram of a semiconductor structure provided by an embodiment of the present disclosure.

FIG. 7 is a schematic diagram of a semiconductor structure provided by an embodiment of the present disclosure.

FIG. 8 is a schematic diagram of a semiconductor structure provided by an embodiment of the present disclosure.

FIG. 9 is a schematic diagram of a semiconductor structure provided by an embodiment of the present disclosure.

FIG. 10 is a schematic diagram of a semiconductor structure provided by an embodiment of the present disclosure.

FIG. 11 is a schematic diagram of a semiconductor structure provided by an embodiment of the present disclosure.

FIG. 12 is a schematic diagram of a semiconductor structure provided by an embodiment of the present disclosure.

FIG. 13 is a flowchart of a manufacturing method of a semiconductor structure provided by an embodiment of the present disclosure.

FIG. 14 is a schematic diagram of a semiconductor intermediate provided by an embodiment of the present disclosure.

FIG. 15 is a schematic diagram of an oxygen doping process provided by an embodiment of the present disclosure.

FIG. 16 is a flowchart of a manufacturing method of a semiconductor structure provided by an embodiment of the present disclosure.

FIG. 17 is a method flowchart of step 13 provided by an embodiment of the present disclosure.

FIG. 18 is a flowchart of a manufacturing method of a semiconductor structure provided by an embodiment of the present disclosure.

### DETAILED DESCRIPTION OF THE EMBODIMENTS

Technical solutions in the embodiments of the disclosure will be clearly and completely described with reference to the accompanying drawings in the embodiments of the disclosure in the following description. Apparently, the described embodiments are only some, not all, embodiments of the disclosure. Based on the embodiments in this disclosure, all other embodiments obtained by those skilled in the art without making creative efforts fall in the protection scope of the present disclosure.

In order to solve the above problems, the present disclosure provides a semiconductor structure, including a substrate, a channel layer, a barrier layer and a P-type semiconductor layer stacked sequentially, where the barrier layer includes a first region and an oxygen-doped region arranged on a side of the first region away from the substrate, an oxygen concentration of the oxygen-doped region is higher than an oxygen concentration of the first region, and a projection of the oxygen-doped region on the substrate at least partially overlaps with a projection of the P-type semiconductor layer on the substrate.

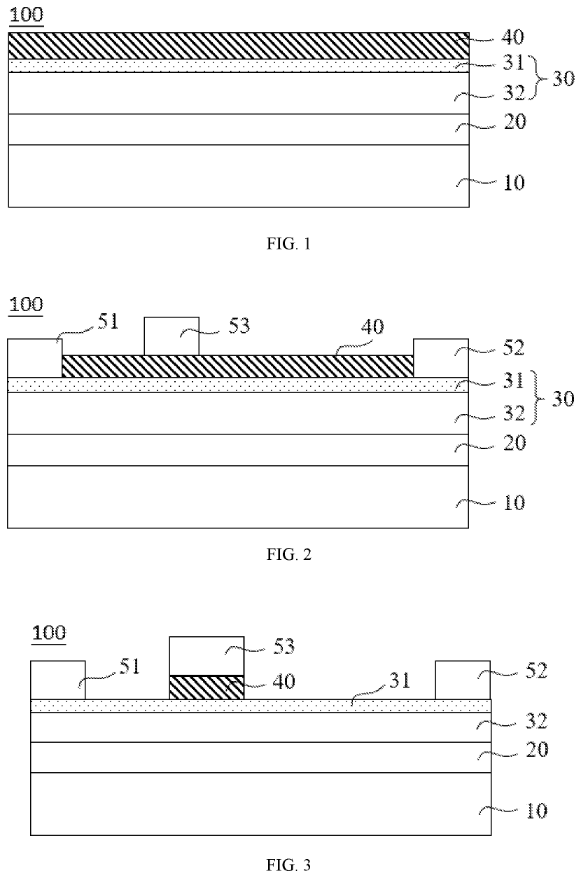

FIG. 1 is a schematic diagram of a semiconductor structure provided by an embodiment of the present disclosure. As shown in FIG. 1, a semiconductor structure 100 includes a substrate 10, a channel layer 20, a barrier layer 30 and a P-type semiconductor layer 40 which are stacked sequentially. The barrier layer 30 includes an oxygen-doped region 31 and a first region 32, an oxygen concentration of the oxygen-doped region 31 is higher than an oxygen concentration of the first region 32, and the oxygen-doped region 31 is arranged on a side of first region 32 away from substrate 10. A projection of oxygen-doped region 31 on the substrate 10 at least partially overlaps with a projection of the P-type semiconductor layer 40 on the substrate 10.

Specifically, as shown in FIG. 1, the oxygen-doped region 31 is arranged on a side of the first region 32 close to the P-type semiconductor layer 40, and the projection of the oxygen-doped region 31 on the substrate 10 at least partially overlaps with the projection of the P-type semiconductor layer 40 on the substrate 10. When the semiconductor structure 100 is in an off state as a power device, the P-type semiconductor layer 40 may deplete 2DEG in the channel, so that the device changes from a depletion mode to an enhancement mode. And then by performing an oxygen doping process to at least part of the barrier layer 30, the oxygen-doped region 31 is obtained where an oxygen concentration of the oxygen-doped region 31 is higher than an oxygen concentration of the first region 32. After the barrier layer corresponding to the oxygen-doped region 31 is doped with oxygen, an unit cell parameter is increased, so that the oxygen-doped region 31 has a wider band gap than the first region 32. Under an electric field, an energy band between the barrier layer 30 and the P-type semiconductor layer 40 bends more, which increases a barrier height for electrons to cross, reduces leakage current, and improves power characteristics of semiconductor device. In other words, the oxygen-doped region 31 is passivated to form an electron blocking layer to block the leakage current that may be formed under a gate electrode, so that the power characteristics of the semiconductor device may be improved.

Specifically, the oxygen concentration refer to a quantity of oxygen atoms per unit volume.

It should be noted that the oxygen-doped region 31 may be obtained by performing the oxygen doping process to the oxygen-doped region 31 of the barrier layer 30 after the barrier layer 30 is formed; or be obtained by introducing a gas source of oxygen element to perform doping process when the oxygen-doped region 31 is generated epitaxially after the first region 32 is epitaxially formed.

Optionally, material of the substrate 10 may be any one of sapphire, silicon, silicon carbide or gallium nitride. Optionally, the channel layer 20, the barrier layer 30 and the P-type semiconductor layer 40 are made from GaN-based materials, for example, material of the channel layer 20 may be GaN, material of the barrier layer 30 may be AlGaN, and material of the P-type semiconductor layer 40 may be P-type GaN. Optionally, before the channel layer 20 is epitaxially formed, a nucleation layer and a buffer layer may be formed epitaxially on a side of the substrate 10, and then the channel layer 20 may be epitaxially formed on a side of the buffer layer away from the substrate 10, which may improve crystal quality of the semiconductor structure.

Optionally, FIG. 2 is a schematic diagram of a semiconductor structure provided by an embodiment of the present disclosure. As shown in FIG. 2, when the semiconductor structure 100 is used as a power device, such as an HEMT, the semiconductor structure 100 further includes a source electrode 51, a drain electrode 52 and a gate electrode 53. The gate electrode 53 is arranged on a side of P-type semiconductor layer 40 away from substrate 10, the source electrode 51 and the drain electrode 52 are arranged on a side of barrier layer 30 away from substrate 10 and located separately on the either side of the gate electrode 53. The source electrode 51 and the drain electrode 52 form an ohmic contact with the barrier layer 30 respectively. When the semiconductor device is in an off state, the P-type semiconductor layer 40 may deplete 2DEG in the corresponding channel layer 20 below the P-type semiconductor layer 40 to obtain an enhancement-mode device; the oxygen-doped region 31 is passivated to form an electron blocking layer, which blocks the leakage current that may occur below the gate electrode 53, and improves the power characteristics of the semiconductor device.

Optionally, in the embodiment of FIG. 2, the source electrode 51 and the drain electrode 52 may directly contact with the first region 32 of the barrier layer 30.

Optionally, FIG. 3 is a schematic diagram of a semiconductor structure provided by an embodiment of the present disclosure. As shown in FIG. 3, a P-type semiconductor layer 40 is located only below a gate electrode 53, so that 2DEG of the corresponding channel layer 20 below the gate electrode 53 may be depleted to obtain an enhancement-mode device.

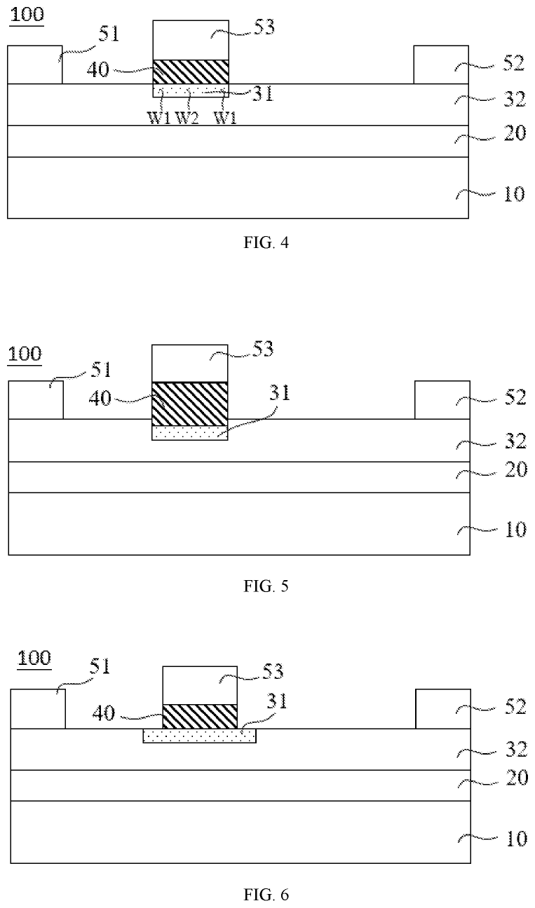

Optionally, the P-type semiconductor layer 40 and the oxygen-doped region 31 of the barrier layer 30 may be performed an oxygen doping process simultaneously, so that the P-type semiconductor layer 40 is activated, Mg—H bond is broken, Mg is released, and electrical activity of Mg is improved, thereby reducing electron scattering and increasing gate voltage during usage. Meanwhile, the oxygen-doped region 31 is passivated to form an electron blocking layer, which improves leakage current. In an embodiment, FIG. 4 is a schematic diagram of a semiconductor structure provided by an embodiment of the present disclosure. As shown in FIG. 4, a surface of the oxygen-doped region 31 away from the substrate 10 and a surface of the first region 32 away from the substrate 10 are in the same plane.

It should be noted that, as shown in FIG. 4, the surface of the oxygen-doped region 31 away from the substrate 10 is equivalent to an upper surface of the oxygen-doped region 31, and the surface of the first region 32 away from the substrate 10 is equivalent to an upper surface of the first region 32, the surface of the oxygen-doped region 31 away from the substrate 10 and the surface of the first region 32 away from the substrate 10 are in the same plane means that the upper surface of the oxygen-doped region 31 is coplanar with the upper surface of the first region 32. After the barrier layer 30 is epitaxially formed, an oxygen doping process is performed to an upper surface of the barrier layer 30, and the upper surface of the barrier layer 30 which is performed the oxygen doping process transforms to the oxygen-doped region 31, and the barrier layer 30 that has not been subjected to the oxygen doping process is the first region 32.

Optionally, as shown in FIG. 4, the oxygen-doped region 31 is only located in a gate electrode region below the P-type semiconductor layer 40, and the oxygen-doped region 31 is not arranged outside the gate electrode region.

Optionally, the oxygen doping process is performed to the barrier layer 30 according to a shape of the P-type semiconductor layer 40, so that a projection area of the P-type semiconductor layer 40 on the substrate 10 is equal to a projection area of the oxygen-doped region 31 on the substrate 10.

Optionally, FIG. 5 is a schematic diagram of a semiconductor structure provided by an embodiment of the present disclosure. As shown in FIG. 5, a concave structure is formed on an upper surface of the barrier layer 30 corresponding to a gate electrode region, and then an oxygen doping process is performed to the upper surface of the barrier layer 30 located in the concave structure to obtain an oxygen-doped region 31. Then a P-type semiconductor layer 40 is epitaxially formed, so that at least part of the P-type semiconductor layer 40 is in the same layer as the barrier layer 30. Forming the concave structure on the barrier layer 30 may be understood as thinning the barrier layer 30 in the gate electrode region, which may reduce polarization charge density in the gate electrode region without affecting channel charge, and realize an enhancement mode while ensuring high output current.

In an embodiment, as shown in FIG. 4, an oxygen concentration of the oxygen-doped region 31 decreases first and then increases in a direction parallel to the substrate 10. It should be understood that, in the direction parallel to substrate 10, an oxygen concentration in an edge region W1 of the oxygen-doped region 31 is higher than an oxygen concentration in a center region W2 of oxygen-doped region 31, and the edge region W1 has a larger unit cell parameter and a wider band gap. Under an electric field, the energy band between the edge region W1 and the P-type semiconductor layer 40 bends more, increasing a height of a potential barrier that electrons have to overcome in the edge region W1, therefore a gate leakage current that easily occurs on a side of the gate electrode 53 or the P-type semiconductor layer 40 is improved.

In an embodiment, FIG. 6 is a schematic diagram of a semiconductor structure provided by an embodiment of the present disclosure. As shown in FIG. 6, a projection area of a P-type semiconductor layer 40 on a substrate 10 is smaller than a projection area of an oxygen-doped region 31 on the substrate 10. It should be noted that an oxygen doping process is performed on a barrier layer 30 in a shape larger than the P-type semiconductor layer 40. Compared with the projection area of the P-type semiconductor layer 40, the projection area of the oxygen-doped region 31 is larger, and the oxygen-doped region 31 may completely cover a gate electrode area, which may avoid leakage current entering a first region 32 through a side of the P-type semiconductor layer 40, thereby the effect of reducing the gate leakage current is better.

Optionally, not all of the projection of the P-type semiconductor layer 40 on the substrate 10 is covered by the oxygen-doped region 31, or, not all of the projection of the oxygen-doped region 31 on the substrate 10 is covered by the P-type semiconductor layer 40.

In an embodiment, a thickness of the oxygen-doped region 31 ranges from 1 nm to 50 nm along a direction perpendicular to the plane where the substrate 10 is located.

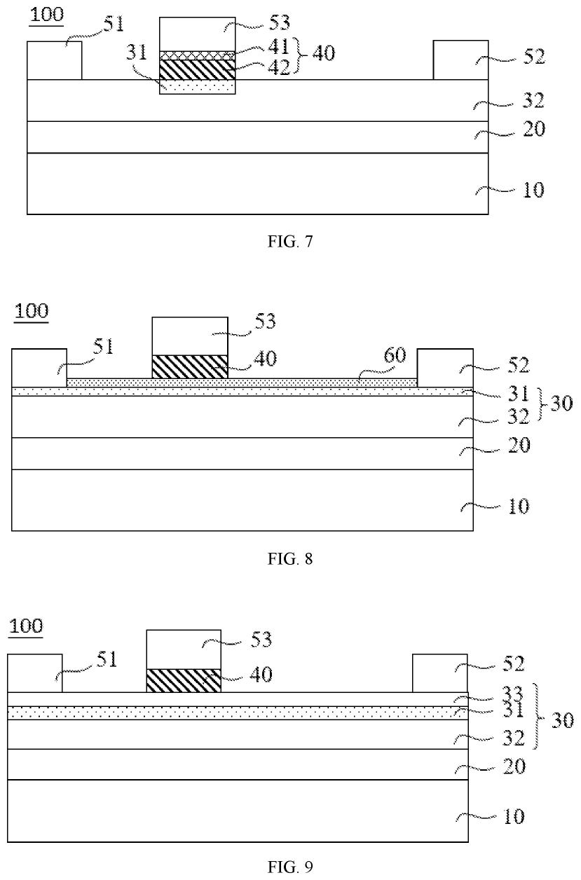

In an embodiment, FIG. 7 is a schematic diagram of a semiconductor structure provided by an embodiment of the present disclosure. As shown in FIG. 7. The P-type semiconductor layer 40 further includes a passivation layer 41 and a first P-type layer 42. The passivation layer 41 is arranged on a side of the first P-type layer 42 away from the substrate 10, and a hydrogen concentration of the passivation layer 41 is higher than a hydrogen concentration of the first P-type layer 42. Specifically, the hydrogen concentration refers to a quantity of hydrogen atoms per unit volume.

It should be noted that, as shown in FIG. 7, compared with the first P-type layer 42 with a low quantity of Mg—H bond, the passivation layer 41 having a higher hydrogen concentration is further away from the substrate 10. The hydrogen concentration of the passivation layer 41 is higher, so that a Mg—H bond is formed and donor Mg is passivated to form a high-resistance structure, which may further reduce gate leakage current in the off state. The same projection area of the P-type semiconductor layer 40 and the oxygen-doped region 31 on the substrate 10 is only taken as an example in FIG. 7, and the present embodiment does not limit whether the projection areas of the P-type semiconductor layer 40 and the oxygen-doped region 31 on the substrate 10 are the same.

In an embodiment, a thickness of the passivation layer 41 ranges from 2 nm to 30 nm along a direction perpendicular to the plane where the substrate 10 is located.

In an embodiment, FIG. 8 is a schematic diagram of a semiconductor structure provided by an embodiment of the present disclosure. As shown in FIG. 8, the semiconductor structure 100 further includes: a gate dielectric layer 60 arranged between a barrier layer 30 and a P-type semiconductor layer 40, where a projection of the gate dielectric layer 60 on a substrate 10 at least partially overlaps with a projection of an oxygen-doped region 31 on the substrate 10, and the gate dielectric layer 60 includes oxides.

Specifically, as shown in FIG. 8, the gate dielectric layer 60 includes AlON or Al₂O₃, which may remove a polarization effect of a gate electrode region and further reduce 2DEG to obtain an enhancement-mode semiconductor device. Optionally, after an oxygen-doped region 31 is formed epitaxially in-situ, an AlN and a P-type semiconductor material layer may be epitaxially formed, and then an oxygen doping process is performed, so that Mg—H bond in the P-type semiconductor material layer is broken and the P-type semiconductor material layer is transformed into the P-type semiconductor layer 40, improving electrical activity of Mg. Meanwhile, AlN is transformed into the gate dielectric layer 60 by oxidation.

In an embodiment, FIG. 9 is a schematic diagram of a semiconductor structure provided by an embodiment of the present disclosure. As shown in FIG. 9, a barrier layer 30 further includes a second region 33 arranged on a side of the oxygen-doped region 31 away from the first region 32, where an oxygen concentration of the oxygen-doped region 31 is higher than an oxygen concentration of the second region 33. It should be understood that the oxygen-doped region 31 may be considered to be obtained by performing an oxygen doping process to a middle layer of the barrier layer 30 in a longitudinal direction. It should be noted that an oxygen concentration of the first region 32 is equal to or not equal to an oxygen concentration of the second region 33.

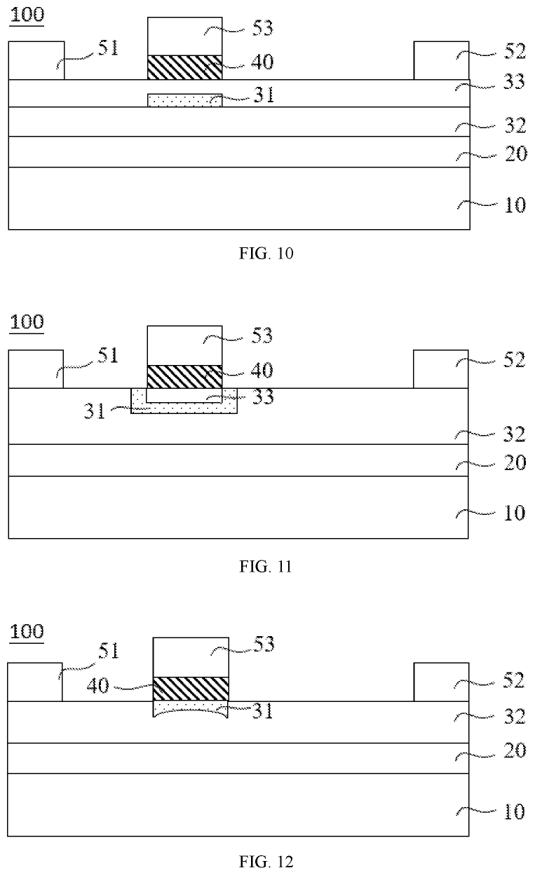

Optionally, FIG. 10 is a schematic diagram of a semiconductor structure provided by an embodiment of the present disclosure. As shown in FIG. 10, an oxygen-doped region 31 is arranged between a first region 32 and a second region 33, and correspondingly arranged below a P-type semiconductor layer 40. Optionally, FIG. 11 is a schematic diagram of a semiconductor structure provided by an embodiment of the present disclosure. As shown in FIG. 11, an oxygen-doped region 31 is arranged between a first region 32 and a second region 33, and surrounds the second region 33. Optionally, the oxygen-doped region 31 is not limited to a right-angled surrounding shape as shown in FIG. 11, and may also be a bowl-shaped surrounding shape (not shown).

In an embodiment, FIG. 12 is a schematic diagram of a semiconductor structure provided by an embodiment of the present disclosure. As shown in FIG. 12, in a direction parallel to a substrate 10, a thickness of an oxygen-doped region 31 decreases first and then increases. It should be noted that gate leakage current tends to occur on a side of a gate electrode 53 or a P-type semiconductor layer 40, so the thicker the oxygen-doped region 31 is close to the side, the better a phenomenon of gate leakage current may be improved.

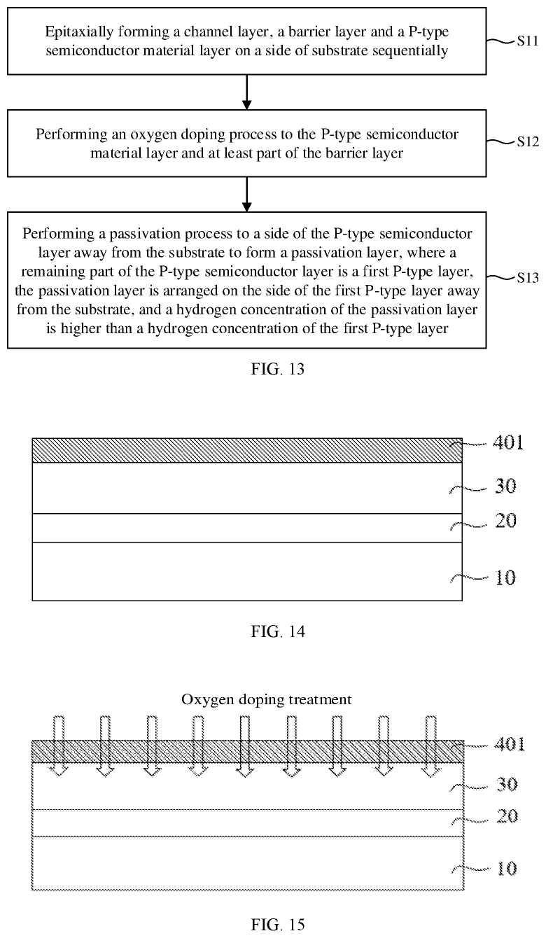

According to another aspect of the present disclosure, FIG. 13 is a flowchart of a manufacturing method of a semiconductor structure provided by an embodiment of the present disclosure, FIG. 14 is a schematic diagram of a semiconductor intermediate provided by an embodiment of the present disclosure, and FIG. 15 is a schematic diagram of an oxygen doping process provided by an embodiment of the present disclosure. The manufacturing method of the semiconductor structure provided by an embodiment of the present disclosure includes: as shown in FIG. 14, step S11, epitaxially forming a channel layer, a barrier layer and a P-type semiconductor material layer on a side of substrate sequentially; as shown in FIG. 15, step S12, performing an oxygen doping process to the P-type semiconductor material layer and at least part of the barrier layer. As shown in FIG. 1, FIG. 14 and FIG. 15, the P-type semiconductor material layer 401 is activated and transformed into a P-type semiconductor layer 40, and the at least part of the barrier layer 30 processed by oxygen doping forms an oxygen-doped region 31, and remaining part of the barrier layer 30 is a first region 32, an oxygen concentration of the oxygen-doped region 31 is higher than an oxygen concentration of the first region 32, the oxygen-doped region 31 is arranged on a side of the first region 32 away from the substrate 10, and a projection of the oxygen-doped region 31 on the substrate 10 at least partially overlaps with a projection of the P-type semiconductor layer 40 on the substrate 10.

It should be noted that in the step S11, an epitaxial manufacturing method includes any one of atomic layer deposition (ALD), chemical vapor deposition (CVD), molecular beam epitaxy (MBE), plasma enhanced chemical vapor deposition (PECVD), low pressure chemical vapor deposition (LPCVD), metal organic compound chemical vapor deposition (MOCVD), and a combination thereof.

It should be noted that in the step S12, material of the P-type semiconductor material layer 401 may be Mg-doped GaN, and after the oxygen doping process, a Mg—H bond in the P-type semiconductor material layer 401 is broken and the P-type semiconductor material layer 401 is transformed into the P-type semiconductor layer 40, which may increase electrical activity of Mg in the P-type semiconductor layer 40 so that 2DEG in the channel may be depleted by the P-type semiconductor layer 40 to realize an enhancement mode. As shown in FIG. 1, an upper surface of barrier layer 30 is transformed into an oxygen-doped region 31 by an oxygen doping process, an oxygen concentration of the oxygen-doped region 31 is higher than an oxygen concentration of the first region 32, the oxygen-doped region 31 is passivated to form an electron barrier layer, which may reduce leakage current and improve power characteristics of semiconductor devices.

In an embodiment, FIG. 16 is a flowchart of a manufacturing method of a semiconductor structure provided by an embodiment of the present disclosure. As shown in FIG. 16, the manufacturing method of the semiconductor structure includes: step S21, epitaxially forming a channel layer and a first region of a channel layer on a side of a substrate sequentially; step S22, epitaxially forming an oxygen-doped region of the barrier layer on a side of the first region away from the substrate by introducing a gas source containing oxygen element, where an oxygen concentration of the oxygen-doped region is higher than an oxygen concentration of the first region and the oxygen-doped region is arranged on a side of the first region away from the substrate; and step S23, forming a P-type semiconductor material layer on a side of the oxygen-doped region away from the substrate, where the P-type semiconductor material layer is activated and transformed into a P-type semiconductor layer and a projection of the oxygen-doped region on the substrate at least partially overlaps with a projection of the P-type semiconductor layer on the substrate.

Specifically, the step S11 may be referred to perform an epitaxial manufacturing method in the step S21; in the step S22, when the oxygen-doped region of the barrier layer is epitaxially formed, the gas source containing oxygen element includes any one of a metalorganic source containing oxygen, a metalorganic source containing H₂O and a metalorganic source containing O₂.

The manufacturing method of the semiconductor structure shown in FIG. 16 includes an oxygen in-situ epitaxy process to the oxygen-doped region of the barrier layer and a process of forming and activating the P-type semiconductor layer. Compared with FIG. 16, in the process of forming the barrier layer shown in FIG. 13, no additional gas source containing oxygen element is needed, the crystal quality of the barrier layer is good, therefore the subsequent oxygen doping process may be performed simultaneously with activation of the P-type semiconductor material layer to form the P-type semiconductor layer and the oxygen-doped region on the barrier layer, simplifying the manufacturing process. It should be noted that, during the oxygen doping process, the activation of the P-type semiconductor material layer may be performed at a temperature lower than 700° C., or the P-type semiconductor material layer may be activated at a high temperature lower than 700° C. after the oxygen doping process. Temperature of a traditional activation process is often higher than 700° C., so an impact of high temperature on a prepared semiconductor structure may be avoided and energy consumption may be reduced under the temperature of the oxygen doping process.

In an embodiment, in the step S12, the oxygen doping process includes any one of oxygen ion implantation, oxygen ion diffusion and ozone process. Specifically, the oxygen ion implantation process uses an inductively coupled plasma-reactive ion etching (ICP-RIE) equipment to ionize oxygen into plasma, and the oxygen plasma falls to the surface of the semiconductor structure to be processes. A speed at which the oxygen plasma falls and a penetration depth of the oxygen plasma into the sample is determined by controlling radio frequency (RF) power. Optionally, the penetration depth of the oxygen plasma reaches at least an upper surface of the barrier layer. Optionally, the oxygen ion diffusion process and the ozone process may be performed to obtain a semiconductor structure in which a projection area of the oxygen-doped region of the barrier layer on the substrate is larger than a projection area of the P-type semiconductor layer on the substrate.

In an embodiment, as shown in FIG. 13, the manufacturing method of a semiconductor structure further includes: step S13, performing a passivation process to a side of the P-type semiconductor layer away from the substrate to form a passivation layer, where a remaining part of the P-type semiconductor layer is a first P-type layer, the passivation layer is arranged on the side of the first P-type layer away from the substrate, and a hydrogen concentration of the passivation layer is higher than a hydrogen concentration of the first P-type layer.

Specifically, as shown in FIG. 7, the passivation process includes hydrogen ion implantation and hydrogen gas injection. A side of the P-type semiconductor 40 away from the substrate 10 is performed the passivation process to transform into a passivation layer 41 with a higher hydrogen concentration. In the passivation layer 41, donor Mg is passivated to form a high-resistance structure, which may further reduce gate leakage current in the off state. Optionally, the thickness of the passivation layer 41 ranges from 2 nm to 30 nm.

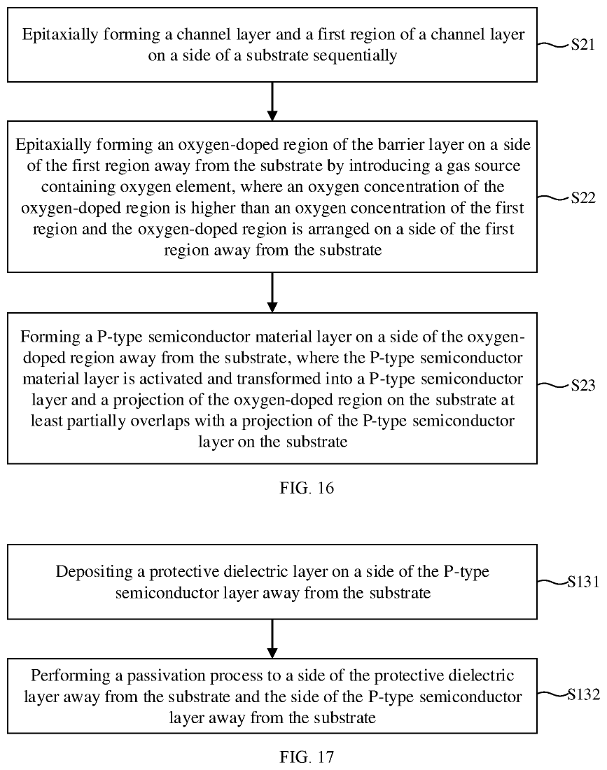

In an embodiment, FIG. 17 is a method flowchart of step S13 provided by an embodiment of the present disclosure. As shown in FIG. 17, step S13 includes: step S131: depositing a protective dielectric layer on a side of the P-type semiconductor layer away from the substrate; step S132: performing a passivation process to a side of the protective dielectric layer away from the substrate and the side of the P-type semiconductor layer away from the substrate.

Specifically, during the passivation process, the protective dielectric layer may control a depth of hydrogen implanted into the surface of the P-type semiconductor layer away from the substrate to obtain a thin passivation layer, such as a passivation layer with a thickness ranging from 2 nm to 30 nm. Optionally, the protective dielectric layer may remain in the final semiconductor structure. Optionally, after the passivation process, the protective dielectric layer is removed by etching. Optionally, material of the protective dielectric layer may be photoresist material or SiO₂.

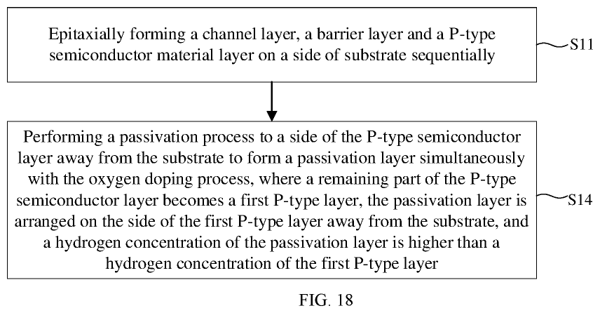

In an embodiment, FIG. 18 is a flowchart of a manufacturing method of a semiconductor structure provided by an embodiment of the present disclosure. As shown in FIG. 18, the method further includes: performing a passivation process to a side of the P-type semiconductor layer away from the substrate to form a passivation layer simultaneously with the oxygen doping process, where a remaining part of the P-type semiconductor layer becomes a first P-type layer, the passivation layer is arranged on the side of the first P-type layer away from the substrate, and a hydrogen concentration of the passivation layer is higher than a hydrogen concentration of the first P-type layer. It should be noted that, in the embodiment shown in FIG. 18, step S12 and step S13 of the embodiment shown in FIG. 13 are performed simultaneously. The combination of step S12 and step S13 is shown as step S14 in FIG. 18.

The present application provides a semiconductor structure and a manufacturing method thereof. The semiconductor structure includes: a substrate, a channel layer, a barrier layer and a P-type semiconductor layer stacked sequentially. The barrier layer includes a first region and an oxygen-doped region arranged on a side of the first region away from the substrate, an oxygen concentration of the oxygen-doped region is higher than an oxygen concentration of the first region, and a projection of the oxygen-doped region on the substrate at least partially overlaps with a projection of the P-type semiconductor layer on the substrate. When the semiconductor device is in an off state, the P-type semiconductor layer may deplete 2DEG in the channel to obtain an enhancement-mode device, and then the oxygen-doped region is obtained by performing an oxygen doping process to at least part of the barrier layer. The oxygen-doped region has a larger unit cell parameter and a wider band gap compared with the first region. Under an electric field, an energy band between the barrier layer and the P-type semiconductor bends more, which increases a barrier height for electrons to cross, reduces leakage current, and improves power characteristics of semiconductor device.

It should be understood that the term of “comprising” and its variants used in this disclosure are open-ended, ie “comprising but not limited to”. The term of “one embodiment” means “at least one embodiment”; the term of “another embodiment” means “at least one further embodiment”. In this specification, the schematic representations of the above terms are not necessarily directed to the same embodiment or example. Furthermore, the described specific features, structures, materials or characteristics may be combined in any suitable manner in any one or more embodiments or examples. In addition, those skilled in the art can combine and combine different embodiments or examples and features of different embodiments or examples described in this specification without conflicting with each other.

The above is only a preferred embodiment of the disclosure, and is not intended to limit the disclosure. Any modifications, equivalent replacements made within the spirit and principles of the disclosure shall be included in the protection scope of the disclosure.

What is claimed is:

1. A semiconductor structure, comprising:
a substrate,
a channel layer,
a barrier layer, and
a P-type semiconductor layer stacked sequentially,
wherein the barrier layer comprises an oxygen-doped region and a first region, an oxygen concentration of the oxygen-doped region is higher than an oxygen concentration of the first region, the oxygen-doped region is arranged on a side of the first region away from the substrate, and a projection of the oxygen-doped region on the substrate at least partially overlaps with a projection of the P-type semiconductor layer on the substrate.

2. The semiconductor structure according to claim 1, wherein a surface of the oxygen-doped region away from the substrate and a surface of the first region away from the substrate are in the same plane.

3. The semiconductor structure according to claim 1, wherein a projection area of the P-type semiconductor layer on the substrate is less than or equal to a projection area of the oxygen-doped region on the substrate.

4. The semiconductor structure according to claim 1, wherein a thickness of the oxygen-doped region ranges from 1 nm to 50 nm along a direction perpendicular to a plane where the substrate is located in.

5. The semiconductor structure according to claim 1, wherein the P-type semiconductor layer comprises a passivation layer and a first P-type layer;
the passivation layer is arranged on a side of the first P-type layer away from the substrate; and
a hydrogen concentration of the passivation layer is higher than a hydrogen concentration of the first P-type layer.

6. The semiconductor structure according to claim 5, wherein a thickness of the passivation layer ranges from 1 nm to 60 nm.

7. The semiconductor structure according to claim 1, further comprising: a gate dielectric layer arranged between the barrier layer and the P-type semiconductor layer, wherein
a projection of the gate dielectric layer on the substrate at least partially overlaps with a projection of the oxygen-doped region on the substrate, and the gate dielectric layer comprises oxides.

8. The semiconductor structure according to claim 1, further comprising:
a gate electrode arranged on a side of the P-type semiconductor layer away from the substrate, a source electrode and a drain electrode arranged on a side of the barrier layer away from the substrate, wherein
the source electrode and the drain electrode are separately arranged on either side of the gate electrode.

9. The semiconductor structure according to claim 1, wherein the barrier layer further comprises a second region arranged on a side of the oxygen-doped region away from the first region, wherein the oxygen concentration of the oxygen-doped region is higher than an oxygen concentration of the second region.

10. The semiconductor structure according to claim 1, wherein an oxygen concentration of the oxygen-doped region decreases first and then increases in a direction parallel to the substrate.

11. The semiconductor structure according to claim 1, wherein a thickness of the oxygen-doped region decreases first and then increases in a direction parallel to the substrate.

12. A manufacturing method of a semiconductor structure, comprising:
epitaxially forming a channel layer, a barrier layer and a P-type semiconductor material layer on a side of the substrate sequentially; and
performing an oxygen doping process to the P-type semiconductor material layer and at least part of the barrier layer;
wherein the P-type semiconductor material layer is activated and transformed to a P-type semiconductor layer, and the at least part of the barrier layer processed by oxygen doping forms an oxygen-doped region, and a remaining part of the barrier layer is a first region, an oxygen concentration of the oxygen-doped region is higher than an oxygen concentration of the first region, the oxygen-doped region is arranged on a side of the first region away from the substrate, and a projection of the oxygen-doped region on the substrate at least partially overlaps with a projection of the P-type semiconductor layer on the substrate.

13. The manufacturing method according to claim 12, wherein the oxygen doping process comprises any one of oxygen ion implantation, oxygen ion diffusion and ozone process.

14. The manufacturing method according to claim 12, further comprising:
performing a passivation process to a side of the P-type semiconductor layer away from the substrate to form a passivation layer,
wherein a remaining part of the P-type semiconductor layer is a first P-type layer, the passivation layer is arranged on the side of the first P-type layer away from the substrate, and a hydrogen concentration of the passivation layer is higher than a hydrogen concentration of the first P-type layer.

15. The manufacturing method according to claim 14, wherein the performing a passivation process to a side of the P-type semiconductor layer away from the substrate to form a passivation layer with remaining part of the P-type semiconductor layer becoming a first P-type layer comprises:
depositing a protective dielectric layer on the side of the P-type semiconductor layer away from the substrate; and
performing the passivation process to a side of the protective dielectric layer away from the substrate and the side of the P-type semiconductor layer away from the substrate.

16. The manufacturing method according to claim 12, further comprising:
performing a passivation process simultaneously with the oxygen doping process to a side of the P-type semiconductor layer away from the substrate to form a passivation layer,
wherein a remaining part of the P-type semiconductor layer becomes a first P-type layer, the passivation layer is arranged on a side of the first P-type layer away from the substrate, and a hydrogen concentration of the passivation layer is higher than a hydrogen concentration of the first P-type layer.

17. A manufacturing method of a semiconductor structure, comprising:
epitaxially forming a channel layer and a first region of a barrier layer on a side of a substrate sequentially;
epitaxially forming an oxygen-doped region of the barrier layer on a side of the first region away from the substrate by introducing a gas source containing oxygen element, wherein an oxygen concentration of the oxygen-doped region is higher than an oxygen concentration of the first region and the oxygen-doped region is arranged on a side of the first region away from the substrate; and
forming a P-type semiconductor material layer on a side of the oxygen-doped region away from the substrate, wherein the P-type semiconductor material layer is activated and transformed into a P-type semiconductor layer and a projection of the oxygen-doped region on the substrate at least partially overlaps with a projection of the P-type semiconductor layer on the substrate.
